(19) United States
(12) Patent Application Publication
(10) Pub. No.: US 2026/0371705 A1
(43) Pub. Date: Nov. 19, 2026

(54) WIRE BONDABLE CAPACITOR ON ACTIVE DIE

(71) Applicant: MACOM Technology Solutions Holdings, Inc., Lowell, MA (US)

(72) Inventors: Donald Patrick Farrell, Raleigh, NC (US); Bradley Millon, Durham, NC (US); Marvin Marbell, Cary, NC (US)

(21) Appl. No.: 19/207,644

(22) Filed: May 14, 2025

(51) Int. Cl. H10D 84/80; H10W 72/50

(52) U.S. Cl. CPC H10D 84/813; H10W 72/5453

(57) ABSTRACT

A transistor circuit includes: a field-effect transistor (FET) device including a gate connected to an input terminal of the transistor circuit, a source connected to a reference voltage of the transistor circuit, and a drain connected to an output terminal of the transistor circuit; and a direct current (DC) blocking capacitor integrated on a same die with the FET device, the DC blocking capacitor comprising a first electrode electrically connected to the reference voltage through at least one conductive via, and a second electrode configured for attachment of a bond wire thereto. The bond wire is connected between the output terminal of the transistor circuit and the second electrode of the DC blocking capacitor and, in conjunction with the DC blocking capacitor, forms at least a portion of an impedance-matching network of the transistor circuit.

### FIELD

The present disclosure relates generally to field-effect transistors (FET) devices, and, more particularly, to FET devices including an integrated capacitor.

### BACKGROUND

For applications such as, but not limited to, high-frequency (e.g., greater than about 200 MHz), high-power applications, it is known to utilize a discrete FET device coupled to an external (i.e., off-chip) impedance-matching network. The off-chip impedance-matching network may include an inductor and a direct current (DC) blocking capacitor connected together in series (e.g., a series L-C network). By effectively matching the output impedance of the FET device to a load coupled to the FET device, maximum power transfer and/or minimum signal reflection may be achieved.

FET devices are often mounted on a printed circuit board, as this allows the FET devices to be conveniently electrically connected to other circuit elements. Conventionally, impedance matching for a FET device has been addressed on the printed circuit board using external (i.e., off-chip) components, such as a separate shunt inductor and a DC blocking capacitor connected together in series between an output of the FET device and ground. Matching the output impedance of the FET device to the impedance of a load coupled to the FET device provides efficient power transfer between the FET device and the load and may reduce the likelihood of signal reflections, generally in the form of oscillations. However, impedance matching using off-chip components can increase parasitic inductance, which reduces the frequency of operation of the FET device, and results in additional external components and assembly time, which can add significant cost to the overall circuit.

Monolithic microwave integrated circuit (MMIC) power amplifiers are known, where the transistor and the matching network are integrated in a single platform. MMICs, which are often used in high-frequency applications, can provide certain advantages over their discrete counterparts, such as reduced size and cost. However, MMIC devices have several disadvantages such as lower output power capability and limited tunability (post-fabrication) which make them unsuitable for many applications.

### SUMMARY

The present invention, as manifested in one or more embodiments, provides an IC device that includes a high-power FET device and an integrated (i.e., on-chip) capacitor which, when coupled with an external (i.e., off-chip) inductor, provides an impedance-matching network for enhancing high-frequency performance and power transfer of the FET device. By integrating the capacitor on the same chip as the FET device, the need for a separate off-chip capacitor to form an impedance-matching network may be avoided. In one or more embodiments, a plate of the on-chip capacitor may be used as a bond pad in the IC device. Utilizing a plate of the on-chip capacitor as a bond pad reduces area consumption in the IC device and may reduce parasitic inductance, thereby increasing a frequency of operation of the FET device.

In accordance with an embodiment of the present disclosure, a transistor circuit includes: an FET device including a gate connected to an input terminal of the transistor circuit, a source connected to a reference voltage of the transistor circuit, and a drain connected to an output terminal of the transistor circuit; and a DC blocking capacitor integrated on a same die with the FET device, the DC blocking capacitor comprising a first electrode electrically connected to the reference voltage through at least one conductive via, and a second electrode configured for attachment of a bond wire thereto. The bond wire is connected between the output terminal of the transistor circuit and the second electrode of the DC blocking capacitor and, in conjunction with the DC blocking capacitor, forms at least a portion of an impedance-matching network of the transistor circuit.

In accordance with another embodiment of the present disclosure, an IC die includes: an FET including a gate configured to receive an input signal provided to the FET, a source connected to a reference voltage through a source via, and a drain configured to present an output signal of the FET; a DC blocking capacitor comprising a first electrode electrically connected to the reference voltage through at least one conductive via, and a second electrode electrically isolated from the first electrode by a dielectric material; and a bond wire having a first end attached to the second electrode of the DC blocking capacitor and having a second end electrically connected to the drain of the FET. The DC blocking capacitor and the bond wire form at least a portion of a series inductor-capacitor (LC) impedance-matching network.

In accordance with still another embodiment of the present disclosure, a method of forming an IC die includes: forming a FET on a semiconductor layer of the IC die, the FET including a gate configured to receive an input signal provided to the FET, a source electrically connected to a reference voltage, and a drain configured to provide an output signal of the FET; forming a DC blocking capacitor on the semiconductor layer, the DC blocking capacitor comprising a first electrode electrically connected to the reference voltage, and a second electrode electrically isolated from the first electrode by a dielectric material; forming first and second bond pads, the first bond pad being electrically connected to the gate of the FET and the second bond pad being electrically connected to the drain of the FET; providing a bond wire having a first end attached to the second electrode of the DC blocking capacitor and having a second end attached to the second bond pad, the bond wire in conjunction with the DC blocking capacitor forming an impedance-matching network of the IC die; and controlling at least one of a length or a diameter of the bond wire for tuning an inductance of the bond wire to provide a prescribed impedance of the impedance-matching network.

Techniques of the present inventive concept can provide substantial beneficial technical effects. By way of example only and without limitation, aspects according to embodiments of the present disclosure may provide one or more of the following advantages, among other benefits:
eliminating the need for an off-chip capacitor in forming an impedance-matching network for a high-frequency FET device;
integrating a portion of an impedance-matching network with the FET device to thereby eliminate the need for wire bonding or other connection structures to off-chip components and thereby reduce parasitic inductance which would otherwise decrease the frequency of operation of the FET device;
reducing overall device cost by eliminating the need for an additional off-chip capacitor which add manufacturing cost as well as assembly cost;
utilizing a plate of the on-chip capacitor as a bond pad reduces area consumption in the IC device, thereby reducing cost.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIGS. 1A-1C are various views schematically depicting at least a portion of an illustrative Group III nitride-based RF transistor amplifier die;

FIG. 2 is a schematic top plan view depicting an illustrative IC die including an active region, a peripheral region surrounding the active area, and a plurality of bond pads;

FIG. 3 is a circuit diagram depicting the illustrative IC die shown in FIG. 1 electrically connected to an off-chip impedance-matching network;

FIG. 4 is a schematic top plan view depicting at least a portion of an illustrative an IC die including a FET device integrated with an on-chip capacitor, according to one or more embodiments of the inventive concept;

FIG. 5 is a schematic diagram depicting at least a portion of a transistor circuit, which may include the illustrative IC die shown in FIG. 3 and a portion of an external impedance-matching network, according to one or more embodiments of the inventive concept;

FIG. 6 is a schematic top plan view depicting at least a portion of an illustrative IC die including an integrated capacitor having a top electrode which functions as a bond pad, according to one or more embodiments of the inventive concept; and

FIG. 7 is a schematic diagram depicting at least a portion of a transistor circuit, which may include the illustrative IC die comprising an integrated capacitor, as shown in FIG. 5, and a portion of an external impedance-matching network, according to one or more embodiments of the inventive concept.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present inventive concept, as manifested in one or more embodiments, may be described herein in the context of a high-frequency field-effect transistor (FET) device, and more specifically to embodiments of a FET device that have an integrated (i.e., on-chip) capacitor configured to be used in conjunction with an external (i.e., off-chip) inductor as a part of an impedance matching network for providing enhanced stability and high-frequency performance, which may be suitable for use with various device fabrication technologies. It is to be appreciated, however, that the inventive concept is not limited to the specific devices, circuits, systems and/or methods illustratively shown and described herein, and moreover is not limited to FET devices operating at any particular frequencies and/or power; that is, any FET device, regardless of power capability or operating frequency, can benefit from aspects of the inventive concept. It will also be apparent to those skilled in the art given the teachings herein that numerous modifications to the embodiments shown are contemplated and are within the scope of embodiments of the claimed invention. That is, no limitations with respect to the embodiments shown and described herein are intended or should be inferred.

Although the overall fabrication method and structures formed thereby as described herein are entirely novel, certain individual processing steps required to implement a portion or portions of the method(s) according to one or more embodiments of the inventive concept may utilize conventional semiconductor fabrication techniques and/or conventional semiconductor fabrication tooling. These techniques and tooling will already be familiar to one having ordinary skill in the relevant art. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are incorporated by reference herein in their entirety. It is emphasized that while some individual processing steps may be set forth herein, those steps are merely illustrative and one skilled in the art may be familiar with other suitable alternatives that would also fall within the scope of the present disclosure.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are contemplated. For example, a region illustrated or described as square or rectangular may have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale.

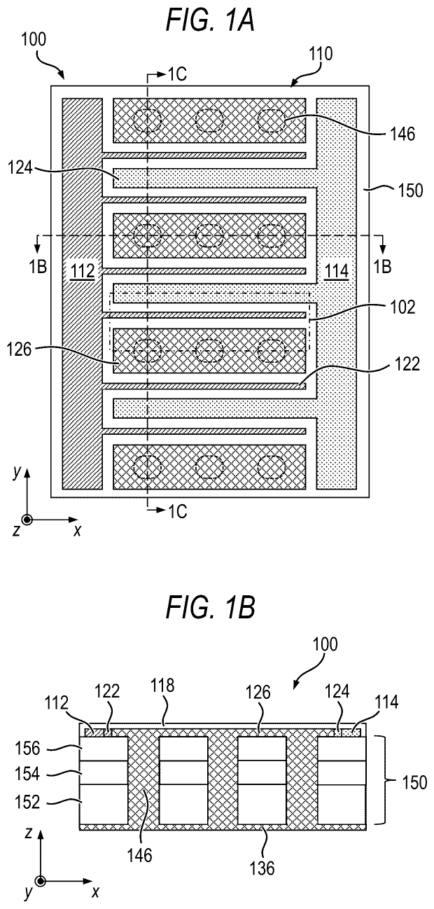

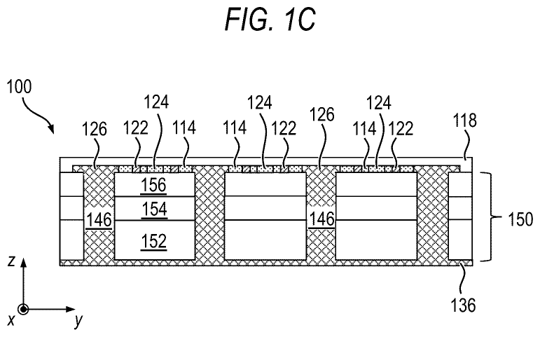

FIGS. 1A-1C are various views schematically depicting at least a portion of an illustrative Group III nitride-based RF transistor amplifier die 100. Specifically, FIG. 1A is a schematic plan view of the RF transistor amplifier die 100. In FIG. 1A, most of the metallization that is typically on the top surface of the semiconductor layer structure has been removed to illustrate the metallization that directly contacts a semiconductor layer structure of the RF transistor amplifier die 100. FIGS. 1B and 1C are schematic cross-sectional views of the RF transistor amplifier die 100 taken along lines 1B-1B and 1C-1C of FIG. 1A, respectively. It will be appreciated that FIGS. 1A-1C (as well as many of the other figures of the present application) are highly simplified diagrams, and that actual RF transistor amplifiers may include many more unit cells and various circuitry and elements that are not shown in the simplified figures herein for economy of description.

Referring to FIG. 1A, the RF transistor amplifier die 100 includes a top side metallization structure 110 that is formed on a semiconductor layer structure 150. The top side metallization structure 110 includes a gate bus 112 and a drain bus 114, a plurality of gate fingers 122, a plurality of drain fingers 124 and a plurality of source fingers 126, all of which are formed on an upper surface of the semiconductor layer structure 150. The gate fingers 122, drain fingers 124 and source fingers 126 may extend in parallel to each other, with the gate fingers 122 extending from the gate bus 112 in a first direction and the drain fingers 124 extending from the drain bus 114 in a direction opposite the first direction. Each gate finger 122 may be positioned between a drain finger 114 and a source finger 126.

The gate bus 112 and the gate fingers 122 may be implemented as a first monolithic metal pattern. The gate fingers 122 may be formed of materials that are capable of making a Schottky contact to a Group III nitride-based semiconductor material, such as nickel (Ni), platinum (Pt), copper (Cu), palladium (Pd), chromium (Cr), tungsten (W) and/or tungsten silicon nitride (WSiN). The gate bus 112 and the gate fingers 122 are part of a gate electrode structure that may form an input of the RF transistor amplifier die 100 for receiving an RF signal provided to the RF transistor amplifier die 100.

The drain bus 114 and the drain fingers 124 may be implemented as a second monolithic metal pattern. The drain fingers 124 may include a metal, such as titanium aluminum nitride (TiAlN), that can form an ohmic contact to Group III nitride-based materials. The drain bus 114 and the drain fingers 124 are part of a drain electrode of the RF transistor amplifier die 100. The upper portion (not shown) of the drain electrode may act as a drain terminal 134 of the RF transistor amplifier die 100 that may form an output of the RF transistor amplifier die 100 for providing an amplifier RF signal provided by the RF transistor amplifier die 100.

The source fingers 126 may include a metal, such as TiAlN, that can form an ohmic contact to Group III nitride-based materials. The source fingers 126 are physically and electrically connected to a source terminal 136 (see FIG. 1B) of the RF transistor amplifier die 100 that is located on a bottom side of the semiconductor layer structure 150 by a plurality of conductive (e.g., metal-plated) source vias 146. Each conductive source via 146 may extend vertically (z-axis direction) from the top metallization structure 110 through the semiconductor layer structure 150. In some embodiments, each conductive source via 146 may be implemented by forming openings through the semiconductor layer structure 150 (e.g., by anisotropic etching) and by then depositing metal-plating that coats the sidewalls of the openings. In some applications, the metal may completely fill the openings so that the conductive source vias 146 are metal-filled vias. The source vias 146 may electrically connect the source fingers 126 to ground or another voltage source (e.g., VSS).

One or more interlayer insulating layers 118 (see FIG. 1B) are formed that isolate the gate metallization 112, 122, the drain metallization 114, 124 and the source metallization 126 from each other. The interlayer insulating layer(s) 118 may include a dielectric material, such as, for example, silicon nitride (SiN), silicon dioxide (SiO₂), etc.

The RF transistor amplifier die 100 includes a plurality of unit cell transistors 102, one of which is indicated in the dashed box in FIG. 1A. The unit cell transistor 102 includes a gate finger 122, a portion of a drain finger 124 and a portion of a source finger 126, along with the portions of the semiconductor layer structure 150 underlying the identified gate finger 122, drain finger 124 and source finger 126. Since all of the gate fingers 122 are electrically connected to a common gate bus 112, all of the drain fingers 124 are electrically connected to a common drain bus 114, and all of the source fingers 126 are electrically connected to a common source terminal 136, it can be seen that the unit cell transistors 102 are all electrically connected together in parallel.

In one or more embodiments, the RF transistor amplifier die 100 may comprise a Group III nitride-based high-electron-mobility transistor (HEMT) RF transistor amplifier. Suitable structures for Group III-nitride-based HEMT devices that may utilize embodiments of the present inventive concept are described, for example, in commonly assigned U.S. Patent Publication Nos. 2002/0066908, 2002/0167023, 2004/0061129, and U.S. Pat. Nos. 7,906,799, and 6,316,793, the disclosures of which are hereby incorporated herein by reference in their entirety.

FIGS. 1B and 1C are schematic cross-sectional views illustrating the semiconductor layer structure 150 in more detail. As shown in FIGS. 1B and 1C, the semiconductor layer structure 150 includes a plurality of semiconductor layers. In the depicted embodiment, a total of two semiconductor layers are shown, namely a channel layer 154 and a barrier layer 156 that is on a top side of the channel layer 154. The semiconductor layer structure 150 may (and typically will) include additional semiconductor and/or non-semiconductor layers. For example, the semiconductor layer structure 150 may include a growth substrate 152 on which the other semiconductor layers are grown. The growth substrate 152 may comprise, for example, a 4H-SiC or 6H-SiC substrate. In other embodiments, the growth substrate 152 may comprise a different semiconductor material (e.g., silicon or a Group III nitride-based material, GaAs, ZnO, InP) or a non-semiconductor material (e.g., sapphire). The growth substrate 152, even if formed of a non-semiconductor material, is considered to be part of the semiconductor layer structure 150.

In some embodiments, the channel layer 154 is a Group III nitride material, such as AlₓGa₁₋ₓN where 0≤x<1, provided that the energy of the conduction band edge of the channel layer 154 is less than the energy of the conduction band edge of the barrier layer 156 at the interface between the channel and barrier layers 154, 156. In certain embodiments, x=0, indicating that the channel layer 154 is gallium nitride (“GaN”). The channel layer 154 may also be formed of other Group III nitrides, such as, for example, indium gallium nitride (InGaN), aluminum indium gallium nitride (AlInGaN) or the like. The channel layer 154 may be undoped or unintentionally doped and may be grown to a thickness of, for example, greater than about 20 angstroms (Å). The channel layer 154 may also be a multi-layer structure, such as a superlattice or combinations of GaN, AlGaN or the like. The channel layer 154 may have a bandgap that is less than the bandgap of at least a portion of the barrier layer 156, and the channel layer 154 may also have a larger electron affinity than the barrier layer 156.

The barrier layer 156 may be a Group III nitride and may have a bandgap larger than that of the channel layer 154 and a smaller electron affinity than the channel layer 154. Accordingly, in certain embodiments of the present invention, the barrier layer 156 may include AlGaN, AlInGaN and/or AlN or combinations of layers thereof. The barrier layer 156 may, for example, be from about 0.1 nm to about 30 nm thick. In certain embodiments, the barrier layer 156 is undoped or doped with an n-type dopant to a concentration less than about 10¹⁹ cm⁻³. In some embodiments, the barrier layer 156 is AlₓGa₁₋ₓN where 0<x<1. In particular embodiments, the aluminum concentration is about 25%. However, in other embodiments of the present invention, the barrier layer 156 comprises AlGaN with an aluminum concentration of between about 5% and about 100%. In specific embodiments of the present invention, the aluminum concentration is greater than about 10%.

A common-source amplifier is one of the basic circuit topologies for a single-stage FET amplifier circuit. In a common-source amplifier, an input signal is provided at a gate terminal of the FET device, and an output signal is provided at a drain terminal of the FET device. A source terminal of the FET device is not used for either an input or an output terminal but is instead considered a common terminal, which is typically connected to ground or another voltage source (e.g., VSS).

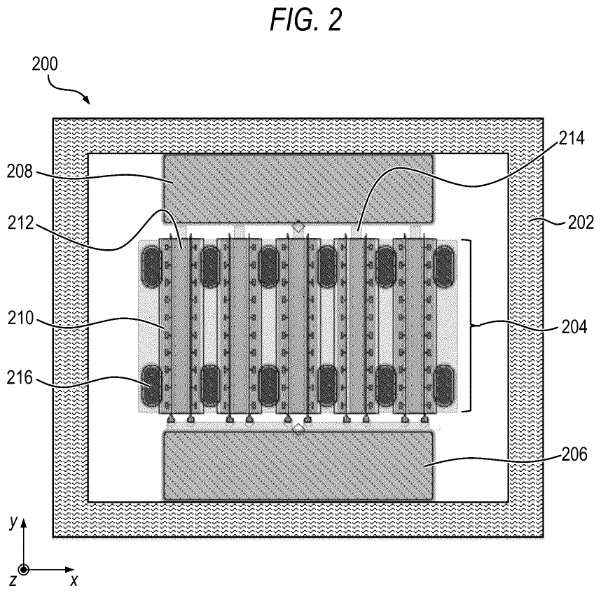

FIG. 2 is a schematic top plan view depicting an illustrative IC die 200 including an IC peripheral region 202 surrounding an active area 204. The active area 204 includes a semiconductor layer structure which may be consistent with the semiconductor layer structure 150 shown in FIGS. 1A through 1C. The IC die 200 further includes a plurality of bond pads. A first one of the bond pads may be an input bond pad 206, and a second one of the bond pads may be an output bond pad 208. A FET device may be formed in the semiconductor layer structure in the active area 204. The die 200 includes a plurality of source contacts 210 and drain contacts 212 formed in the active area 204 of the FET device.

Each of the source contacts 210 and drain contacts 212 may extend in a first direction (e.g., y-axis direction), parallel to a surface of the semiconductor layer structure in which the source and drain contacts 210, 212 are formed and are electrically connected to underlying source and drain regions, respectively, formed in the semiconductor layer structure (e.g., source fingers 126 and drain fingers 124 shown in FIGS. 1A-1C) . The term “connected” (or “connecting,” or like terms such as “contact” or “contacting”), as may be used herein, is intended to refer to a physical and/or electrical connection between two or more elements, and may include other intervening elements unless the context indicates otherwise. As used herein, the term “and/or” includes any and all combinations of one or more of the associated listed items. The source and drain contacts 210, 212 are alternatively arranged in a second direction (e.g., x-axis direction) parallel to the surface of the semiconductor layer structure and intersecting the first direction, so that each source contacts 210 is adjacent to a drain contacts 212 in the second direction.

The die 200 further includes a plurality of gate fingers 214 extending over the active area 204 in the first direction, with each gate finger 214 disposed between a pair of adjacent source and drain contacts 210, 212. Source vias 216 that extend through the semiconductor layer structure are provided in the active area 204 for electrically connecting the respective source contacts 210 to ground, or an alternative reference voltage (e.g., VSS).

The source vias 216 may electrically connect the source contacts 210 (which are metal connections formed on an upper surface of the semiconductor layer structure) to a metal layer on the back side of the semiconductor layer structure that is often referred to as a backside metal layer. The backside metal layer is typically connected to a reference voltage such as ground. Respective portions of the active area 204 under the gate fingers 214, between adjacent source and drain contacts 210, 212, form channel regions of the FET device. In this example embodiment, the FET device may include a plurality of unit cell transistors, with each gate of a unit cell transistor comprising a plurality of gate fingers 214. Each of the gate fingers 214 is connected to the input bond pad 206, and each of the drain contacts 212 is connected to the output bond pad 208.

In one or more illustrative embodiments, the FET device may be formed from Group III-V elemental semiconductor materials, including, for example, Group III nitrides, gallium arsenide (GaAs), indium phosphide (InP), indium gallium phosphide (InGaP), aluminum gallium arsenide (AlGaAs), and compounds thereof. As used herein, the term “Group III nitride” refers to those semiconducting compounds formed between nitrogen and the elements in Group III of the periodic table, usually aluminum (Al), gallium (Ga), and/or indium (In). The term also refers to ternary and quaternary compounds, such as AlGaN and AlInGaN. These compounds have empirical formulas in which one mole of nitrogen is combined with a total of one mole of the Group III elements. In example embodiments, the FET device may be formed from Group IV elemental semiconductor materials, including silicon (Si), germanium (Ge), and compounds thereof. For example, the FET device may be a Group III-nitride based HEMT RF transistor amplifier that is implemented in gallium nitride (GaN) based semiconductor epitaxial layers that are formed on a silicon carbide (SiC) substrate, although embodiments of the present invention are not limited thereto. In one or more embodiments, the IC die 200 may be a Group III nitride based die including at least one FET device. The FET device may comprise, for example, a HEMT device, although embodiments are not limited thereto. The HEMT device may, for example, be used to implement an RF transistor amplifier.

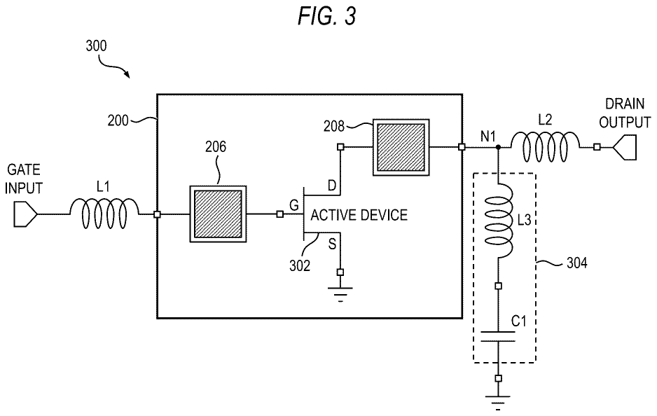

FIG. 3 is a schematic diagram depicting at least a portion of a transistor circuit 300, which may include the illustrative IC die 200 shown in FIG. 2, and an external impedance-matching network. Referring to FIG. 3, the IC die 200 comprises an active device, which may be a FET device 302, configured as a common-source amplifier. Specifically, the FET device 302 includes a gate terminal (G) electrically connected to a first bond pad, which may the input bond pad 206, a drain terminal (D) electrically connected to a second bond pad, which may be the output bond pad 208, and a source terminal(S) connected to ground, or an alternative voltage source (e.g., VSS). A gate input of the transistor circuit 300 is provided at the input bond pad 206 through a first inductor L1. A drain output of the transistor circuit 300 is provided at the output bond pad 208 through a second inductor L2. The inductors L1 and L2 may represent parasitic inductances of the respective bond wires and/or other connections or elements disposed between the input and output bond pads 206, 208 and a package lead frame associated with the IC die 200.

The transistor circuit 300 further includes an external (i.e., off-chip) impedance-matching network 304 connected to the output bond pad 208 at a first node N1. The impedance-matching network 304 may be configured as a series inductor-capacitor (LC) network which includes a shunt inductor L3 and a direct current (DC) blocking capacitor C1 connected in series between the first node N1 and ground. As previously stated, impedance matching using off-chip components can increase parasitic inductance, which reduces the frequency of operation of the FET device 302, and results in additional external components and assembly time, which can add significant cost to the transistor circuit 300. One approach to reducing parasitic components in the transistor circuit 300 is to integrate the DC blocking capacitor C1 of the impedance-matching network 304 in the IC die 200.

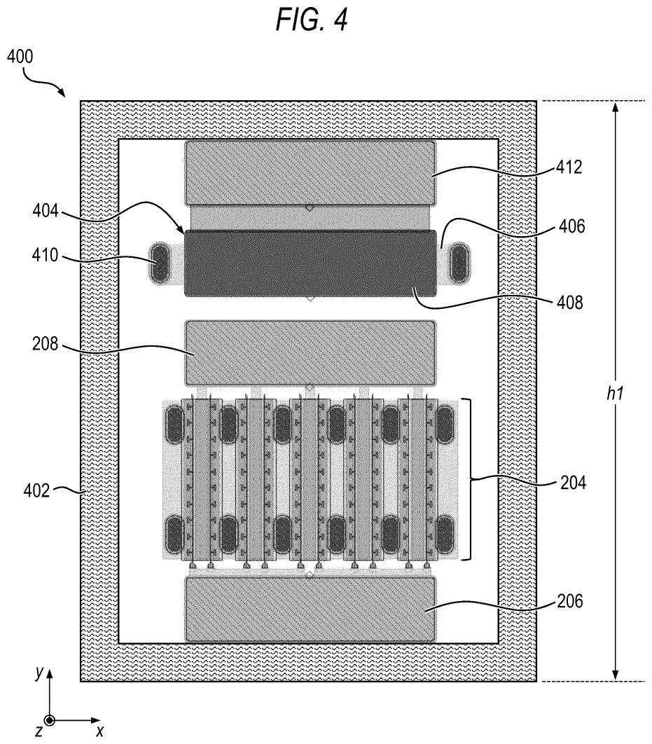

FIG. 4 is a schematic top plan view depicting at least a portion of an illustrative IC die 400 including a FET device integrated with an on-chip capacitor, according to one or more embodiments of the inventive concept. Like the IC die 200 depicted in FIG. 2, the IC die 400 includes a peripheral region 402 surrounding the active area 204, and input and output bond pads 206, 208. The active area 204 may include the semiconductor layer (e.g., 150 in FIGS. 1A-1C) in which a FET device is formed in a manner consistent with the illustrative FET device shown in FIG. 2. The IC die 400 further includes an on-chip capacitor 404 comprising a first electrode 406 and a second electrode 408 that is electrically isolated from the first electrode 406 by a dielectric or other insulating material (not explicitly shown) disposed between the first and second electrodes 406, 408. In this manner, the first and second electrodes 406, 408 may be separated from each other in the vertical (z-axis) direction.

The first electrode 406 may form a bottom plate of the capacitor 404 and the second electrode 408 may form a top plate of the capacitor 404. The first and second electrodes 406, 408 may be configured so that they at least partially overlap one another in the vertical (z-axis) direction, perpendicular to the surface of the semiconductor layer structure in which the FET device is formed. As used herein, “an element A overlapping an element B in a direction X” (or similar language) means that there is at least one line that extends in the direction X and intersects both the elements A and B. Each of the first and second electrodes 406, 408 of the capacitor 404 may comprise a metal, such as, for example, aluminum or copper, or other conductive material(s), although embodiments are not limited thereto. The first electrode 406 may be electrically connected to ground, or another voltage source, using one or more conductive vias 410. The second electrode 408 may be electrically connected to a third bond pad 412 for providing an external electrical connection to the capacitor 404.

The capacitor 404, when used in conjunction with an external (i.e., off-chip) inductor, may form an impedance-matching network consistent with the impedance-matching network 304 shown in FIG. 3. By integrating the capacitor 404 on the IC die 400, a reduction in parasitic inductance may be achieved, thereby improving high-frequency performance of the FET device. As a trade-off, however, a separate bond pad 412 is required in this example embodiment, which may increase the overall area of the IC die 400.

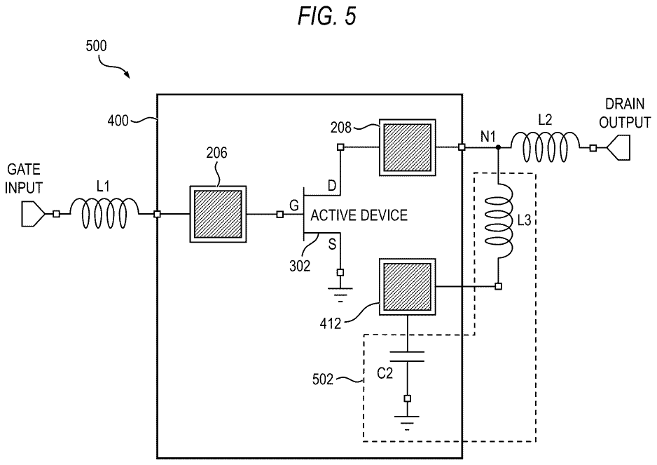

FIG. 5 is a schematic diagram depicting at least a portion of a transistor circuit 500, which may include the illustrative IC die 400 shown in FIG. 4 and a portion of an external impedance-matching network, according to one or more embodiments of the present disclosure. Referring to FIG. 5, the IC die 400 comprises an active device, which may be the FET device 302, configured as a common-source amplifier. Specifically, the FET device 302 includes a gate terminal electrically connected to a first bond pad, which may the input bond pad 206, a drain terminal electrically connected to a second bond pad, which may be the output bond pad 208, and a source terminal connected to ground, or an alternative voltage source (e.g., VSS) through one or more conductive vias (e.g., vias 216 shown in FIG. 2). A gate input of the transistor circuit 500 is provided at the input bond pad 206 through the first inductor L1. A drain output of the transistor circuit 500 is provided at the output bond pad 208 through the second inductor L2. The inductors L1 and L2 may represent parasitic inductances of the respective bond wires and/or other connections or elements disposed between the input and output bond pads 206, 208 and a package lead frame associated with the IC die 400.

The transistor circuit 500 further includes an impedance-matching network 502 connected to the output bond pad 208 at the first node N1. Unlike the impedance-matching network 304 shown in FIG. 3 which is entirely off-chip, the impedance-matching network 502 may be configured as a series LC network which includes an off-chip inductor and an on-chip capacitor. More particularly, the impedance-matching network 502 includes the external (off-chip) shunt inductor L3 and a DC blocking capacitor C2 which is integrated on the IC die 400; that is, the DC blocking capacitor C2 is an on-chip capacitor. A first terminal of the shunt inductor L3 is connected to the output bond pad 208 at the first node N1, a first electrode of the on-chip DC blocking capacitor C2 is electrically connected to ground, such as through the one or more conductive vias 410 (see FIG. 4), and a second electrode of the on-chip DC blocking capacitor C2 is electrically connected to the off-chip shunt inductor L3 through the third bond pad 412. At least a portion of the total inductance of the shunt inductor L3 may be attributable to a wire bond between the second bond pad 208 and the third bond pad 412.

While integrating the DC blocking capacitor C2 of the impedance-matching network 502 onto the IC die 400 may reduce parasitic inductance in the transistor circuit 500, thereby improving high-frequency performance of the transistor circuit 500, such improved high-frequency performance comes at the expense of increased IC die area due, at least in part, to the additional bond pad 412 in the IC die 400. Furthermore, added connections between the on-chip DC blocking capacitor C2 and the bond pad 412 may increase the presence of parasitic elements (e.g., inductance) which can undesirably affect high-frequency performance of the FET device 302.

It is to be appreciated that RF amplifiers often include matching circuits, such as impedance matching networks, that are designed to improve the impedance match between an RF amplifier die (e.g., IC die 400) and transmission lines connected thereto for RF signals at the fundamental operating frequency and harmonic termination circuits that are designed to at least partly terminate harmonics that may be generated during device operation such as second-and third-order harmonics. The RF amplifier die(s) as well as the impedance matching and harmonic termination circuits may be enclosed in a package. Electrical leads may extend from the package that are used to electrically connect the RF amplifier to external circuit elements such as input and output RF transmission lines and bias voltage sources.

Conventional Group III nitride-based RF amplifiers may use bond wires to connect the IC die (e.g., 400) to gate and drain leads (e.g., gate input and drain output, respectively, of the transistor circuit 500). These bond wires have inherent inductance that may be used to implement some of the inductors in the impedance matching and/or harmonic termination circuits of the RF amplifiers (e.g., impedance matching network 502 in FIG. 5). The amount of inductance provided may be varied by changing the length and/or the cross-sectional area (e.g., the diameter) of the bond wires so that the bond wires provide a desired amount of inductance. In this manner, the inductance may be tuned to meet required design parameters of the transistor circuit 500.

Unfortunately, as applications move to higher frequencies, the inductance of the bond wires may exceed a desired amount of inductance for the impedance matching and/or harmonic termination circuits. When this occurs, bond wires that are very short and/or that have large cross-sectional areas may be used in an effort to decrease the inductance thereof to suitable values. Very short bond wires, however, may be difficult to solder in place, which may increase manufacturing costs, and/or may result in higher device failure rates. Bond wires having large cross-sectional areas may require larger gate and/or drain bond pads on the IC die, which require an increase in the overall size of the IC die, which is also undesirable. Moreover, in some higher frequency applications, even very short bond wires having large cross-sectional areas may have too much inductance such that the matching networks cannot, for example, properly terminate the second-or third-order harmonics. While the RF amplifiers may be implemented as monolithic microwave integrated circuit (MMIC) devices in order to avoid the problem of too much inductance in the bond wires, MMIC RF amplifiers are more expensive to fabricate, cannot be easily tuned post-fabrication, and can only be used in a narrow frequency range, therefore reducing flexibility and tunability.

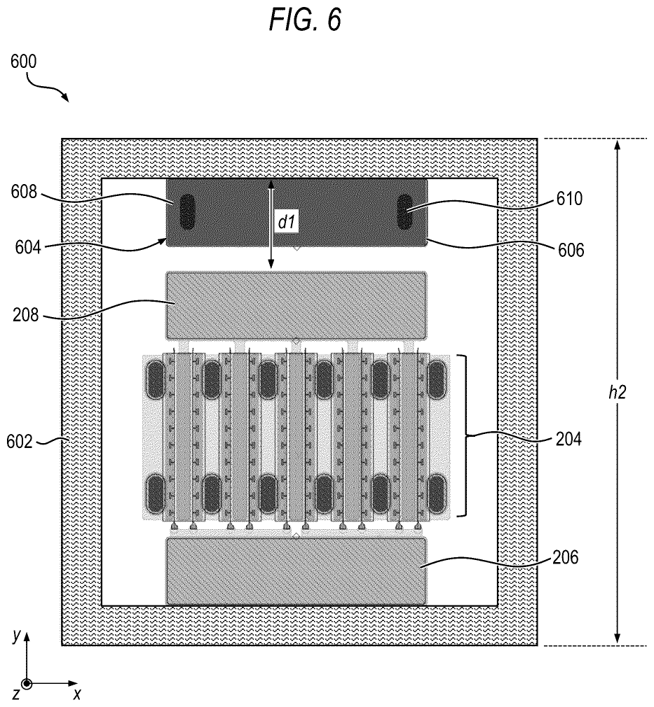

In order to provide enhanced high-frequency performance without a significant increase in chip area or cost, a top plate of the integrated (i.e., on-chip) capacitor forming a portion of the impedance-matching network 402 may be used as a bond pad, thereby eliminating the need for the separate third bond pad 412 and related connections and associated parasitic components (e.g., parasitic inductance). By way of example only and without limitation, FIG. 6 is a schematic top plan view depicting at least a portion of an illustrative IC die 600 including an integrated capacitor, according to one or more embodiments of the present disclosure. Like the IC die 400 depicted in FIG. 4, the IC die 600 of FIG. 6 includes a peripheral region 602 surrounding an active area 204. The active area 204 includes a semiconductor layer structure which may be consistent with the semiconductor layer structure 150 shown in FIGS. 1A through 1C. The IC die 600 further includes a plurality of bond pads, including input and output bond pads 206 and 208, respectively. The active area 204 may include a FET device formed in a manner consistent with the illustrative FET device of FIGS. 2 and 4. In one or more embodiments, the FET device comprises a plurality of fingers, each of the plurality of fingers comprising a source contact and a source via (e.g., 216 in FIG. 2) connecting the source contact and underlying source region of the semiconductor layer structure to a reference voltage of the IC die 600, such as ground or VSS.

The IC die 600 further includes a capacitor 604 comprising a first electrode 606 and a second electrode 608 that is electrically isolated from the first electrode 606 by a dielectric or other insulating material (not explicitly shown) disposed between the first and second electrodes 606, 608. In this manner, the first and second electrodes 606, 608 may be separated from each other in the vertical (z-axis) direction. The first electrode 606 may be a bottom plate of the capacitor 604 and the second electrode 608 may be a top plate of the capacitor 604. The first and second electrodes 606, 608 may be configured so that they at least partially overlap one another in the vertical (z-axis) direction, perpendicular to the surface of the semiconductor layer structure in which the FET device is formed.

Each of the first and second electrodes 606, 608 of the capacitor 604 may comprise a metal (e.g., aluminum or copper) or other conductive material, although embodiments are not limited thereto. The first electrode (i.e., bottom plate) 606 of the on-chip capacitor 604 may be electrically connected to ground, or another voltage source (e.g., VSS), using one or more conductive vias 610. In one or more embodiments, the conductive vias 610 may be moved underneath the capacitor 604 to reduce parasitics. The second electrode (i.e., top plate) 608 of the on-chip capacitor 604 is configured as a bond pad for providing an external connection to the capacitor 604, thereby eliminating the need for an additional separate bond pad in the IC die 600.

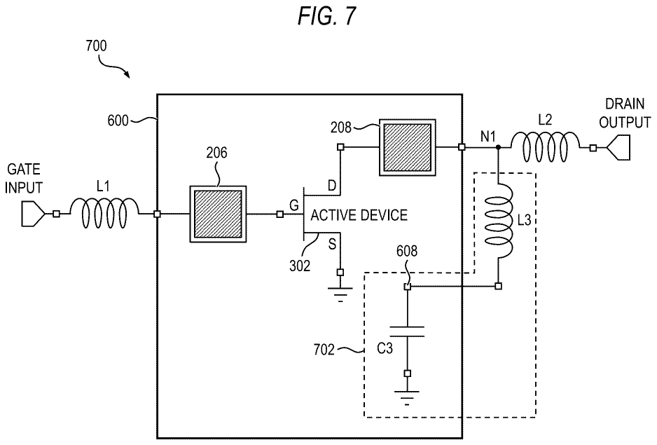

The configuration shown in FIG. 6 reduces the area consumed by the IC die 600 compared to the illustrative IC die 400 depicted in FIG. 4. For example, the IC die 400 shown in FIG. 4 may have a first height, h1, in the y-axis direction which is greater than a second height, h2, in the y-axis direction of the IC die 600 shown in FIG. 6, with a width in the x-axis direction of each of the IC dies 400 and 600 being about the same. By utilizing the second electrode 608 as a bond pad, parasitic inductance in the IC die 600 may be further reduced. Moreover, a distance, d1, in the y-axis direction, from an edge of the second bond pad 208 to a peripheral edge of the IC die 600 is reduced (compared to the layout arrangement for the IC die 400 shown in FIG. 4), which helps the shunt matching inductance (e.g., L3 in FIG. 7) in the impedance-matching network achieve lower values, which is particularly beneficial for higher operating frequencies of the FET device. For example, in one or more embodiments, the distance d1 between the edge of the second bond pad 208 to the peripheral edge of the IC die 600 may be reduced to about 175 μm or less. This approach allows a minimum inductance that may achieved for the shunt inductor L3 to be about 75 picohenry (pH) or less per bond wire, which may not be achievable using the configuration shown in FIG. 4. With the configuration shown in FIG. 4, the bond wire would be much longer. The configuration of the IC die 600 shown in FIG. 6 can therefore achieve superior high-frequency performance compared to the configuration shown in FIG. 4.

Using the configuration shown in FIG. 4, the second electrode 408 of the capacitor 404 and the second bond pad 412 can be reversed, allowing the same bond wire length to be used as for the configuration shown in FIG. 6. However, the configuration shown in FIG. 6 still provides advantages because having the bond pad 412 separated from the second electrode 408 of the capacitor 404, as shown in FIG. 4, adds parasitic inductance of about 10 pH. The effective minimum inductance for the bond wire using the arrangement of FIG. 4 would thus be about 85 pH, compared to about 75 pH for the same length bond wire using the arrangement shown in FIG. 6. This parasitic inductance is per bond wire. For large transistors, many bond wires may be used in parallel, providing a lower overall inductance using the arrangement of FIG. 6.

FIG. 7 is a schematic diagram depicting at least a portion of a transistor circuit 700, which may include the illustrative IC die 600 shown in FIG. 6 and a portion of an external impedance-matching network, according to one or more embodiments of the present disclosure. Referring to FIG. 7, the IC die 600 comprises an active device, which may be the FET device 302, configured as a common-source amplifier. Specifically, the FET device 302 includes a gate terminal electrically connected to a first bond pad, which may the input bond pad 206, a drain terminal electrically connected to a second bond pad, which may be the output bond pad 208, and a source terminal connected to ground, or an alternative voltage source (e.g., VSS) through one or more conductive vias (e.g., vias 216 shown in FIG. 2). A gate input of the transistor circuit 700 is provided at the input bond pad 206 through the first inductor L1. A drain output of the transistor circuit 700 is provided at the output bond pad 208 through the second inductor L2. The inductors L1 and L2 may represent parasitic inductances of the respective bond wires and/or other connections or elements disposed between the input and output bond pads 206, 208 and a package lead frame associated with the IC die 600.

The transistor circuit 700 further includes an impedance-matching network 702 connected to the output bond pad 208 at the first node N1. The impedance-matching network 702, consistent with the impedance-matching network 502 shown in FIG. 5, may be configured as a series LC network which includes the external (off-chip) shunt inductor L3 and a DC blocking capacitor C3 which is integrated on the IC die 600; that is, the DC blocking capacitor C3 is an on-chip capacitor. More particularly, a first terminal of the shunt inductor L3 is connected to the output bond pad 208 at the first node N1, and a first electrode of the on-chip DC blocking capacitor C3 is electrically connected to ground, such as through the one or more conductive vias 610 (see FIG. 6). A second terminal of the off-chip shunt inductor L3 is electrically connected to the on-chip DC blocking capacitor C3 integrated on the IC die 600 using the second electrode (i.e., top plate) of the DC blocking capacitor C3 as a bond pad.

In one or more embodiments, a bond wire between the second bond pad 208 and the top plate of the on-chip DC blocking capacitor C3 may form at least a portion of an inductance of the shunt inductor L3 in the impedance-matching network 702. Configured in this manner, the transistor circuit 700 may achieve improved high-frequency performance without sacrificing chip area. Alternatively or additionally, for the same area consumed by the IC die 400 shown in FIG. 4, the omission of the third bond pad (412 in FIGS. 4 and 5) in the IC die 600 may allow a larger DC blocking capacitor C3 having higher capacitance to be integrated onto the IC die 600, thereby providing more control over the design and tuning of the impedance-matching network 702 to meet prescribed frequency and stability requirements of the transistor circuit 700. In one or more embodiments, a length and/or diameter of the bond wire between the second bond pad 208 and the top plate of the DC blocking capacitor C3 and/or a size of the DC blocking capacitor C3 are configured to tune an impedance of the impedance-matching network 702 to prescribed frequency parameters of the transistor circuit 700.

In order to utilize the top plate of the on-chip DC blocking capacitor as a bond pad, certain design criteria may need to be implemented in the IC fabrication process. For example, prescribed minimum dimensions for the top plate of the on-chip DC blocking capacitor (e.g., in the x-axis and/or y-axis direction) may be required in order to ensure proper wire bonding to the top plate of the capacitor C3. In one or more embodiments, the dimensions of the top plate of the on-chip DC blocking capacitor C3 may be configured to be at least 2.5 to 3 times the diameter of the wire being used for bonding, with a minimum size of about 50-100 microns (μm) on each side. Additionally, one or more IC fabrication design rules may be modified to facilitate wire bonding to the top plate of the on-chip DC blocking capacitor C3.

For example, for bonding to the top plate of the on-chip DC blocking capacitor C3, an IC fabrication design rule may be included (or modified) specifying a minimum distance between a conductive via (e.g., via 610 in FIG. 6) under the on-chip DC blocking capacitor C3 and a bonding area on the second electrode (top plate) of the on-chip capacitor C3. A design rule checking (DRC) program may be configured to verify that the IC layout adheres to this minimum distance specification. In one or more embodiments, an additional layer may be added to the IC fabrication and chip design rule (i.e., DRC) library (e.g., CAP_OPEN_layer) which is used for identifying areas to open in a passivation layer above a capacitor during the DRC process. Standard IC fabrication and chip design rule libraries (i.e., DRC libraries) only include a layer (e.g., PAD_OPEN_layer) used for opening the passivation layer above bond-pad metallization with no capacitor underneath. The new layer may be incorporated into the fabrication mask used for manufacturing an IC die.

It will be understood that although ordinal terms, such as first, second, etc., may be used herein to describe various elements, these elements should not be limited by such terms. These terms are only used to distinguish one element from another. For example, a first element could be termed a second element, and, similarly, a second element could be termed a first element, without departing from the scope of the present disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” as may be used herein, are intended to specify the presence of stated features, integers, steps, operations, elements, and/or components, but do not necessarily preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms used herein should be interpreted as having a meaning that is consistent with their meaning in the context of the present disclosure and the relevant art and will not be interpreted in an idealized or overly formal sense unless expressly so defined herein.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

Relative terms such as “below,” “above,” “upper,” “lower,” “horizontal,” “lateral,” and/or “vertical,” may be used herein to describe a relationship of one element, layer or region to another element, layer or region as illustrated in the figures. It will be understood, however, that these terms are intended to encompass different orientations of the device in place of or in addition to the orientation depicted in the figures.

In the drawings and specification, there have been disclosed illustrative embodiments of the invention and, although specific terms are employed, they are used in a generic and descriptive sense only and not for purposes of limitation, the scope of the invention being set forth in the following claims.

1. A transistor circuit, comprising:
a field-effect transistor (FET) device including a gate connected to an input terminal of the transistor circuit, a source connected to a reference voltage of the transistor circuit, and a drain connected to an output terminal of the transistor circuit; and
a direct current (DC) blocking capacitor integrated on a same die with the FET device, the DC blocking capacitor comprising a first electrode electrically connected to the reference voltage through at least one conductive via, and a second electrode configured for attachment of a bond wire thereto,
wherein the bond wire is connected between the output terminal of the transistor circuit and the second electrode of the DC blocking capacitor and, in conjunction with the DC blocking capacitor, forms at least a portion of an impedance-matching network of the transistor circuit.

2. The transistor circuit of claim 1, wherein the at least one conductive via is disposed underneath the DC blocking capacitor.

3. The transistor circuit of claim 1, further comprising a first bond pad connected to the gate of the FET device and a second bond pad connected to the drain of the FET device.

4. The transistor circuit of claim 3, wherein the DC blocking capacitor is electrically connected to the second bond pad through the bond wire.

5. The transistor circuit of claim 1, wherein the FET device and the DC blocking capacitor are disposed on a Group III nitride semiconductor layer structure.

6. The transistor circuit of claim 1, wherein the FET device comprises a plurality of fingers, each of the plurality of fingers comprising a source and a source via connecting the source to the reference voltage of the transistor circuit.

7. The transistor circuit of claim 1, wherein a length of the bond wire and/or a size of the DC blocking capacitor are configured to tune an impedance of the impedance-matching network to prescribed frequency parameters of the transistor circuit.

8. The transistor circuit of claim 1, wherein the FET device is a Group III-nitride based high electron mobility transistor (HEMT) comprising gallium nitride based semiconductor epitaxial layers formed on a silicon carbide substrate.

9. The transistor circuit of claim 1, wherein a minimum inductance of the bond wire is about 75 picohenries.

10. The transistor circuit of claim 1, wherein a minimum length of the bond wire is about 175 microns.

11. An integrated circuit (IC) die, comprising:
a field-effect transistor (FET) including a gate configured to receive an input signal provided to the FET, a source connected to a reference voltage through a source via, and a drain configured to present an output signal of the FET;
a direct current (DC) blocking capacitor, the DC blocking capacitor comprising a first electrode electrically connected to the reference voltage through at least one conductive via, and a second electrode electrically isolated from the first electrode by a dielectric material; and
a bond wire having a first end attached to the second electrode of the DC blocking capacitor and having a second end electrically connected to the drain of the FET,
wherein the DC blocking capacitor and the bond wire form at least a portion of a series inductor-capacitor (LC) impedance-matching network.

12. The IC die of claim 11, further comprising at least one bond pad electrically connected to the drain of the FET, wherein the second end of the bond wire is attached to the at least one bond pad.

13. The IC die of claim 11, wherein the at least one conductive via is disposed underneath the DC blocking capacitor.

14. The IC die of claim 11, wherein the FET and the DC blocking capacitor are disposed on a Group III nitride semiconductor layer structure.

15. The IC die of claim 11, wherein the FET comprises a plurality of fingers, each of the plurality of fingers comprising a source and a source via connecting the source to the reference voltage of the transistor circuit.

16. The IC die of claim 11, wherein the FET is a Group III-nitride-based high electron mobility transistor (HEMT) comprising gallium nitride based semiconductor epitaxial layers formed on a silicon carbide substrate.

17. The IC die of claim 11, wherein at least one of a length or a diameter of the bond wire is tuned to provide a prescribed inductance for the impedance-matching network.

18. The IC die of claim 17, wherein a maximum inductance of the bond wire is about 75 picohenries.

19. The IC die of claim 17, wherein a maximum length of the bond wire is about 175 microns.

20. A method of forming an integrated circuit (IC) die, the method comprising:
forming a field-effect transistor (FET) on a semiconductor layer of the IC die, the FET including a gate configured to receive an input signal provided to the FET, a source electrically connected to a reference voltage, and a drain configured to provide an output signal of the FET;
forming a direct current (DC) blocking capacitor on the semiconductor layer, the DC blocking capacitor comprising a first electrode electrically connected to the reference voltage, and a second electrode electrically isolated from the first electrode by a dielectric material;
forming first and second bond pads, the first bond pad being electrically connected to the gate of the FET and the second bond pad being electrically connected to the drain of the FET;
providing a bond wire having a first end attached to the second electrode of the DC blocking capacitor and having a second end attached to the second bond pad, the bond wire in conjunction with the DC blocking capacitor forming an impedance-matching network of the IC die; and
controlling at least one of a length or a diameter of the bond wire for tuning an inductance of the bond wire to provide a prescribed impedance of the impedance-matching network.

21. (canceled)
